(19) United States
(12) Patent Application Publication
(10) Pub. No.: US 2006/0278918 A1
(43) Pub. Date: Dec. 14, 2006

(54) Semiconductor device and method for fabricating the same

(76) Inventor: Yoko Inoue, Aizuwakamatsu-shi (JP)

Correspondence Address: INGRASSIA FISHER & LORENZ, P.C., 7150 E. CAMELBACK, STE. 325, SCOTTSDALE, AZ, 85251, US

(21) Appl. No.: 11/441,771

(22) Filed: May 26, 2006

Related U.S. Application Data
(63) Continuation of application No. PCT/JP05/09879, filed on May 30, 2005.

(51) Int. Cl. H01L 29/788

(52) U.S. Cl. 257/316

(57) ABSTRACT

A semiconductor device includes a bit line formed in a semiconductor substrate, a first interconnection line provided above the bit line and connected to the bit line, and a second interconnection line provided above the first interconnection line and connected to the first interconnection line and a transistor in a peripheral region. The first interconnection line is connected to the transistor through the second interconnection line only.

### CROSS-REFERENCE TO RELATED APPLICATIONS

This is a continuation of International Application No. PCT/JP2005/009879 filed May 30, 2005 which was not published in English under PCT Article 21(2).

### BACKGROUND OF THE INVENTION

1. Field of the Invention

The present invention relates to semiconductor devices and methods for the same, and more particularly, to a semiconductor device having an ONO film and its fabrication method.

2. Description of the Related Art

Recently, non-volatile memories that are programmable semiconductor devices have been widely used. In the past, floating gate type flash memories were widely employed in which charge is stored in the floating gate. As miniaturization of memories for achievement of a higher memory density progresses, it becomes more difficult to efficiently design the floating gate type flash memories. The miniaturization of memory cells of the floating gate type needs thinning of the tunnel oxide film. However, the thinning of the tunnel oxide film increases leakage current flowing through the tunnel oxide film. Further, the tunnel oxide film becomes more defective, which may lose charge stored in the floating gate. Thus, the floating gate type flash memories are less reliable.

Taking the above drawbacks into consideration, flash memories having an ONO (Oxide/Nitride/Oxide) film have been proposed. Examples of these flash memories are of MONOS (Metal Oxide Nitride Oxide Silicon) type or SONOS (Silicon Oxide Nitride Oxide Silicon) type. This type of flash memories stores charge in a silicon nitride layer that is sandwiched between silicon oxide layers and is called trap layer. Since charge is stored in the silicon nitride film that is an insulator film, the charge is not lost even when the tunnel oxide film is defective. This is quite different from the floating gate type. Further, multiple bits of data expressing multiple values can be stored in the trap layer of the single memory cell. This contributes a great deal to improvement in the memory capacity of the flash memories.

For example, U.S. Pat. No. 6,011,725 discloses a transistor having two charge storage regions located between a gate electrode and a semiconductor substrate. The source and drain of the transistor are interchanged for symmetrical operation. This discriminates the source and drain regions over each other. Further, the bit line is functionally combined with the source region and the drain region, and is buried in the semiconductor substrate. This achieves miniaturization of memory cells.

However, further miniaturization of memory cells may cause charge stored in the trap layer in the ONO film to be lost. If part of the charge is lost from the ONO film, data stored will be lost. This causes a serious problem about the reliability of flash memories.

### SUMMARY OF THE INVENTION

The present invention has an object to provide a highly reliable semiconductor device in which lost of charge from the ONO film can be suppressed and a method of fabricating such a semiconductor device.

According to an aspect of the present invention, there is provided semiconductor device including: a bit line formed in a semiconductor substrate; a first interconnection line provided above the bit line and connected to the bit line; and a second interconnection line provided above the first interconnection line and connected to the first interconnection line and a transistor in a peripheral region, wherein the first interconnection line is connected to the transistor through the second interconnection line only. The first interconnection line is not connected directly to the transistor in the peripheral region but is connected thereto via the second interconnection line. It is thus possible to restrain the ONO film 12 from being damaged due to charge up caused at the time of forming the interconnection lines and to improve the reliability of the semiconductor device.

The first interconnection line may be formed in the core region or a region between the core region and the peripheral region only. It is thus possible to more reliably restrain the ONO film from being damaged and to suppress charge loss from the ONO film.

The semiconductor device may further include a third interconnection line connected to the second interconnection line and the transistor, wherein the second interconnection line is connected to the transistor through the third interconnection line only. It is thus possible to prevent the surface of the first interconnection line from being over etched at the time of forming a contact hole and to thus reduce the contact resistance between the contact hole and the first interconnection line. It is thus possible to restrain the charge that is charged up in the first interconnection line.

The semiconductor device may further include an ONO film provided on the bit line and having a contact hole through which the bit line and the transistor are connected. The charge loss from the ONO film can be restrained.

According to another aspect of the present invention, there is provided a semiconductor device including: a bit line formed in a semiconductor substrate; an interlayer insulating film provided above the bit line; and a first interconnection layer provided on the interlayer insulating film and connected to the bit line through a contact hole formed in the interlayer insulating film, wherein the interlayer insulating film has a dummy contact hole connected to the first interconnection line and the semiconductor substrate, the dummy contact hole being connected to a portion of the first interconnection line between a transistor in a peripheral region and the bit line. Since the dummy contact hole is connected to the first interconnection line, it is thus possible to cause the charge developed by charge up at the time of forming the interconnection lines to flow to the semiconductor substrate via the dummy contact hole and to thus restrain the ONO film from being damaged. The charge loss from the ONO film can be restrained, and the reliability of the semiconductor device can be improved.

The dummy contact hole may be formed in a core region or a region between the core region and the peripheral region. It is thus possible to more reliably restrain the ONO film from being damaged and to suppress charge loss from the ONO film.

The dummy contact hole may be connected to a dummy diffused region formed in the semiconductor substrate. It is thus possible to more reliably restrain the ONO film from being damaged and to suppress charge loss from the ONO film.

The semiconductor device may further include; an ONO film provided between the bit line and the interlayer insulating film, wherein the contact hole is formed in the ONO film. The charge loss from the ONO film can be restrained.

The above the peripheral region may be a select cell area. It is thus possible to restrain the charge loss from the ONO film in the core region connected to a transistor of the select cell area.

According to yet another aspect of the present invention, there is provided a method of fabricating a semiconductor device including: forming a bit line in a semiconductor substrate; forming a first interconnection line, above the bit line, connected to the bit line; and forming a second interconnection line, above the first interconnection line, connected to the first interconnection line and a transistor in a peripheral region, wherein the first interconnection line is connected to the transistor through the second interconnection line only. It is thus possible to restrain the ONO film from being damaged due to charge up caused at the time of forming interconnection lines and to thus provide the highly reliable semiconductor device.

The step of forming the first interconnection line may further include a step of forming a third interconnection line connected to the transistor and to be connected the second interconnection line. It is possible to prevent the first interconnection line from being over etched when a contact hole is formed in the peripheral circuit region and to reduce the contact resistance between the contact hole and the first interconnection line. It is also possible to restrain charge in the first interconnection line due to charge up.

The method may further include forming an ONO film on the semiconductor substrate, the first interconnection line being connected to the bit line through the contact hole formed in the ONO film. The charge loss from the ONO film can be restrained.

According to a further aspect of the present invention, there is provided a method of fabricating a semiconductor device including: forming a bit line on a semiconductor substrate; forming an interlayer insulating film above the bit line; forming a contact hole, in the interlayer insulating film, connected to the bit line; and forming a first interconnection line, on the interlayer insulating film, connected to a transistor in a peripheral region and the bit line, wherein the step of forming the contact hole includes a step of forming a dummy contact hole connected to the semiconductor substrate and for connection to the first interconnection line between the transistor and the bit line. The dummy contact hole is connected to the first interconnection line. It is thus possible to cause charge that is charged up at the time of forming interconnection lines to flow to the semiconductor substrate via the dummy contact hole and to restrain the ONO film from being damaged. Therefore, the reliability of the semiconductor device fabrication method can be improved.

The step of forming the bit line may include a step of forming a dummy diffused region in the semiconductor substrate for connection to the dummy contact hole. It is thus possible to more reliably cause the charge due to charge up to flow to the semiconductor substrate and to restrain the ONO film from being damaged.

The method may further include forming an ONO film on the semiconductor substrate, wherein the step of forming the contact hole includes a step of forming the contact hole in the ONO film. It is possible to restrain the charge loss from the ONO film.

The method may be configured so that the peripheral region is a core select cell area. It is thus possible to restrain the charge loss from the ONO film in the core region connected to a transistor of the select cell area.

### BRIEF DESCRIPTION OF THE DRAWINGS

FIGS. 1(a) and 1(b) show a cause of charge loss from a trap layer in which FIG. 1(a) is a plan view of a flash memory and FIG. 1(b) is a cross-sectional view taken along a line A-A shown in FIG. 1(b);

FIGS. 2(a) and 2(b) show a structure of a flash memory in accordance with a first embodiment, in which FIG. 2(a) is a plan view of the flash memory and FIG. 2(b) is a cross-sectional view taken along a line A-A shown in FIG. 2(a);

FIGS. 3(a) through 3(d) are cross-sectional views showing a method of fabricating the flash memory in accordance with the first embodiment;

FIGS. 4(a) and 4(b) show a structure of a flash memory in accordance with a second embodiment, in which FIG. 4(a) is a plan view of the flash memory and FIG. 4(b) is a cross-sectional view taken along a line A-A shown in FIG. 4(a);

FIGS. 5(a) and 5(b) are cross-sectional views of the flash memory of the second embodiment;

FIGS. 6(a) and 6(b) show a structure of a flash memory in accordance with a third embodiment, in which FIG. 6(a) is a plan view of the flash memory and FIG. 6(b) is a cross-sectional view taken along a line A-A shown in FIG. 6(a);

FIGS. 7(a) and 7(b) are cross-sectional views showing a method of fabricating the flash memory of the third embodiment; and

FIG. 8 is a plan view of a variation of the flash memory of the third embodiment.

### DESCRIPTION OF THE PREFERRED EMBODIMENTS

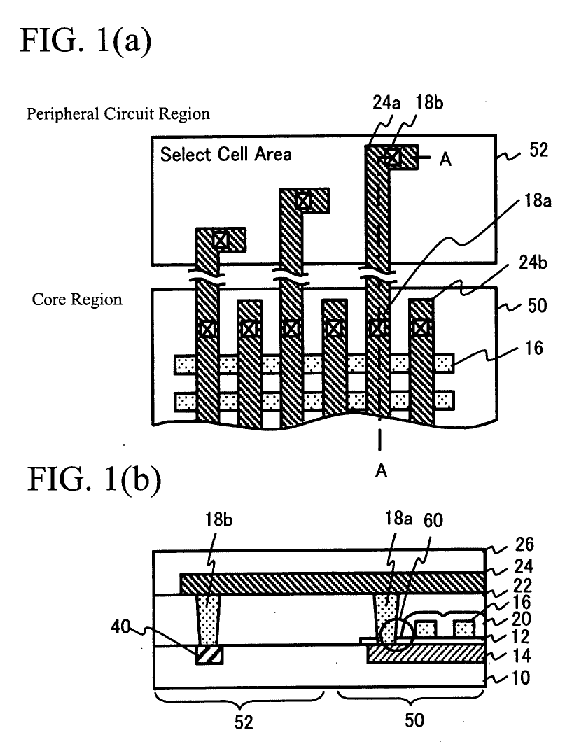

A cause of charge loss from the ONO film was founded out by the present inventors, and will now be described with reference to FIGS. 1(a) and 1(b). FIG. 1(a) is a plan view of a flash memory having an ONO film (a protection film and an interlayer insulating film are not illustrated), and FIG. 1(b) is a cross-sectional view taken along a line A-A shown in FIG. 1(a). The flash memory has a core region 50 in which memory cells are arranged, and a peripheral circuit region 52 in which a select cell area and input/output circuits are provided. In the core region 50, bit line 14 are buried in a semiconductor substrate 10. An ONO film 12 including a trap layer is formed on the semiconductor substrate 10. Word lines 16 are formed on the ONO film 12. In the peripheral circuit region 52, a transistor is formed in the semiconductor substrate 10, and a diffused region 40 of the transistor is buried in the semiconductor substrate 10. A silicon oxide film 20 is formed on the word lines 16, and an interlayer insulating film 22 is formed on the semiconductor substrate 10. Contact holes 18a and 18b are formed in the interlayer insulating film 22. The bit lines 14 and the diffused regions 40 are connected to first and second interconnection lines 24a and 24b via the contact holes 18a and 18b. A passivation film 26 is formed on the first interconnection lines 24a and 24b.

The first interconnection lines 24a and 24b extend over the bit lines 14 within the core region 50, and are connected to the bit lines 14 every predetermined number of word lines 16. This arrangement is intended to reduce the influence of the bit line resistance to the transistors in the core region 50. The first interconnection lines 24a extend up to the select cell area in the peripheral circuit region 52 every other line, and are connected, via the contact holes 18b, to the diffused regions 40 of the transistors in the peripheral circuit region 52. The first interconnection lines 24b that do not extend up to the select cell area in FIG. 1(a) extend to another select cell area (another peripheral circuit region) on the side opposite to the side shown in FIG. 1(a), and are connected to diffused regions 40 of transistors (which may be sector select transistors) formed in the other side select cell area. The select cell area forms a peripheral circuit that functions to select cells in the core region 50, and the sector select transistors are those having the function of selecting cells in the core region 50.

The present inventors investigated memory cells in which charge loss takes place and found out that charge loss frequently occurs in cells that are connected to the first interconnection lines 24a connected to the select cell area and are located in an end of the core region 50. Further, the inventors presumed the following from the results of the investigation.

Generally, the substrate surface is charged up in dry etching with plasma. When the first interconnection lines 24 are formed, charge does not flow in only a specific contact hole if the entire surface is covered with a metal layer (aluminum) from which the first interconnection lines 24 are formed. When etching progresses and the metal layer is then patterned into the first interconnection lines 24a, the charges gather in the first interconnection lines 24a between the contact holes 18b connected to the diffused regions 40 and the contact holes 18a connected to the bit lines 14. This gathering of charges is facilitated due to a long distance between the bit lines 14 and the diffused regions 40, which distance is generally equal to 1.5-9.5 μm. Thus, a large amount of charge gathers in the first interconnection lines 24a. No contact holes are provided in the first interconnection lines 24a between the contact holes 18a and 18b. This causes the charges to flow to the semiconductor substrate 10 through the closest contact holes 18a. This flow of charges may damage the ONO film 12 in regions 60 close to the contact holes 18a. An exemplary damage of the ONO film 12 is a contamination of the ONO film 12 with metal or hydrogen. The damage of the ONO film 12 loses the charge from the ONO film 12. The charges may flow in the transistors in the peripheral circuit region 52. However, this does not cause any substantive problem because the transistors are stronger than the ONO film 12.

Now, a description will be given of embodiments of the present invention directed to restraining the charge loss from the ONO film 12.

### First Embodiment

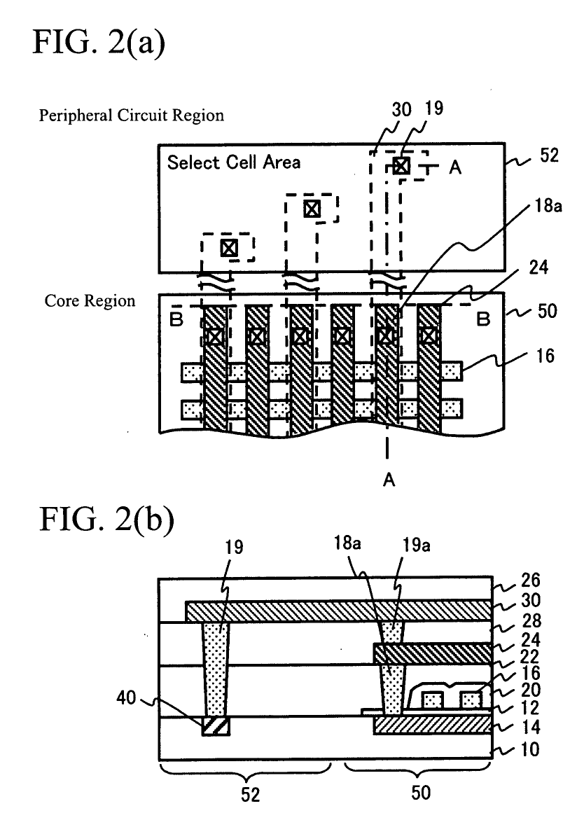

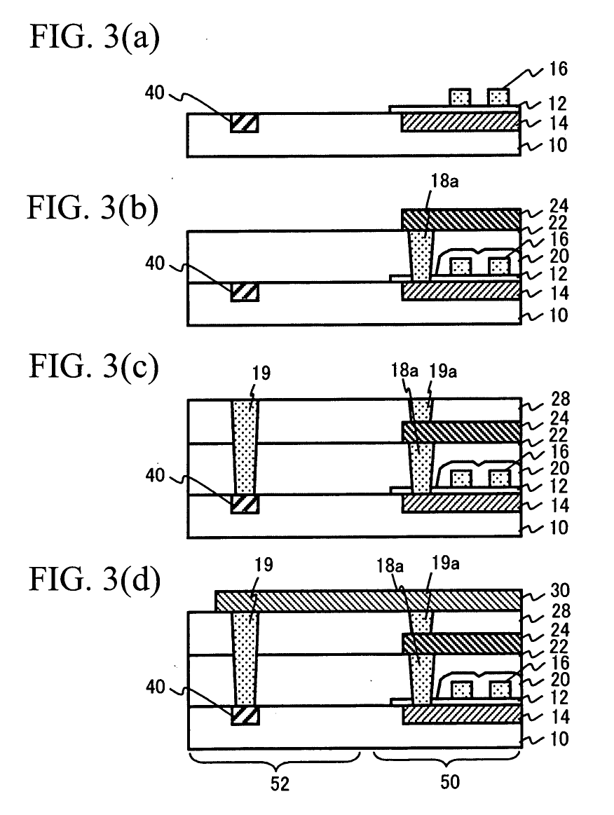

A first embodiment does not use the first interconnection lines for making connections between the transistors in the peripheral circuit region and the bit lines, but employs second interconnection lines provided on the first interconnection lines. FIG. 2(a) is a plan view of the first embodiment (in which the passivation film 26 and the interlayer insulating films 22 and 28 are not illustrated, and second interconnection lines 30 are illustrated by broken lines). FIG. 2(b) is a cross-sectional view taken along line a line A-A shown in FIG. 2(a). FIGS. 3(a) through 3(d) illustrate a method of fabricating the first embodiment, and show cross-sections corresponding to the cross section shown in FIG. 2(b). First, the fabrication method of the first embodiment is described.

Referring to FIG. 3(a), the ONO film 12 is formed on the p-type silicon semiconductor substrate 10 (or a p-type region in the semiconductor substrate 10). The ONO film 12 may be formed by forming the tunnel oxide film (silicon oxide film) by thermal oxidization and forming the trap layer (silicon nitride film) and the top oxide film (silicon oxide film) by CVD. The ONO film 12 in the peripheral circuit region 52 will be removed later. Arsenic is implanted in a given region in the semiconductor substrate 10 in the core region 50 so as to form the bit lines 14, which function as the source and drain regions buried in the semiconductor substrate 10. The word lines 16, which may be formed by a polysilicon film, are formed in a given region on the ONO film 12 in the core region 50 so that the word lines 16 run in the direction of the widths of the bit lines 14. Then, the transistors in the peripheral circuit region 52 are formed. FIG. 3(a) shows one of the diffused regions thus formed.

Referring to FIG. 3(b), the silicon oxide film 20 is formed so as to cover the word line 16. This process is intended to bury the areas between the word lines 16 with an insulation film. The silicon oxide film 20 is formed on the entire surface. As the first interlayer insulating film 22, a silicon oxide film such as BPSG (Boro-Phospho-Silicated Glass) may be formed by CVD. The contact holes 18a connected to the bit lines 14 are formed in the first interlayer insulating film 22 and the ONO film 12. The contact holes 18a are buried with a metal, which may be Ti/WN or Ti/TiN and W. The first interconnection lines 24, which may be made of aluminum, are formed in give regions on the first interlayer insulating film 22 (that is, bit lines 14). The first interconnection lines 24 run in the longitudinal directions of the bit lines 14, and are connected to only the bit lines via the contact holes 18a formed in the first interlayer insulating film 22 and the ONO film 12. That is, the first interconnection lines 24 are not connected directly to the transistors in the peripheral region 52 via the contact holes 18 formed in the first interlayer insulating film 22. The peripheral circuit region 52 may be the select cell area, and the transistors may be sector select transistors.

The first interconnection lines 24 may be formed on the entire surface of the first interlayer insulating film 22 by sputtering aluminum to form a metal layer and forming a photoresist pattern by the ordinary exposure technique. The aluminum layer is etched by an RIE apparatus of high-density plasma type with a chlorine-based gas. That is, the metal (aluminum) layer connected to only the bit lines 14 are etched to form the first interconnection lines 24. At that time, the first interconnection lines 24 are not connected to the transistors in the peripheral circuit region 52. As compared to the flash memory shown in FIGS. 1(a) and 1(b), the first interconnection lines 24 are short. The shortened length of the first interconnection lines 24 reduces the amount of charge that is charged up in the first interconnection lines 24 and reduces the currents flowing through the contact holes 18a. Thus, the ONO film 12 close to the contact holes 18a is less damaged.

Referring to FIG. 3(c), a silicon oxide film similar to the first interlayer insulating film 22 is formed, as a second interlayer insulating film 28, on the first interlayer insulating film 22 and the first interconnection lines 24. Then, the contact holes 19 and 19a are simultaneously formed. The contact holes 19 are formed in the second interlayer insulating film 28 and the first interlayer insulating film 22, and are connected to the diffused regions 40 of the transistors in the peripheral circuit region 52. The contact holes 19a are formed in the second interlayer insulating film 28 and are connected to the first interconnection lines 24. The contact holes 19 and 19a are buried with, for example, Ti/WN or Ti/TiN and W.

Referring to FIG. 3(d), an aluminum layer (metal layer) is formed on the entire surface of the second interlayer insulating film 28 by sputtering, and a photoresist pattern is formed thereon by the ordinary exposure technique. The aluminum layer is etched by the RIE apparatus of high-density plasma type with a chlorine-based gas. This process results in second interconnection lines 30 connected to the first interconnection lines 24 and the diffused regions 40 in the peripheral circuit region 52. In etching, the charges pass through the second interconnection lines 30 and flow in the contact holes 19a. It is to be noted that the first interconnection lines 24 are connected to the contact holes 19a, so that the charge is distributed to the contact holes 18a and the first interconnection lines 24. This reduces the amount of charge that flows in the contact holes 18a, and reduces damage of the ONO film 12 close to the contact holes 18a.

Finally, the passivation film 26 is formed on the second interlayer insulating film 28 and the second interconnection lines 30, and the flash memory of the first embodiment is completed.

Referring to FIGS. 2(a) and 2(b) again, the flash memory of the first embodiment has the bit lines 14 buried in the semiconductor substrate 10, and the first interconnection lines 24 provided above the first interconnection lines 24 and are connected thereto. Further, the flash memory has the second interconnection lines 30, which are provided above the first interconnection lines 24 and connect the first interconnection lines 24 and the diffused regions 40 of the transistors in the peripheral circuit region 52. The first interconnection lines 24 are connected to the diffused regions 40 via only the second interconnection lines 30. As in the case of the first embodiment, the peripheral circuit region is the select cell area, and the transistors are sector select transistors.

The second interconnection lines 30 extend up to the peripheral circuit region 52 every other line, and are connected to the transistors provided therein. The first interconnection lines 24 that are not connected to the second interconnection lines 30 are connected, via the second interconnection lines 30, to the transistors in the peripheral circuit region 52 located at the other side. The arrangement of the select cell areas provided at the both sides of the core region 50 enables the peripheral circuits to be arranged efficiently.

Preferably, the first interconnection lines 24 do not extend to the peripheral circuit regions 52 but terminate within the core region 50 or areas between the core region 50 and the peripheral circuit regions 52. It is thus possible to shorten the lengths of the first interconnection lines 24 and to reduce the charges that gather to the first interconnection lines 24 when the lines 24 are formed. It is thus possible to reliably reduce the damage of the ONO film 12 and restrain charge loss from the ONO film 12.

In the first embodiment, the first interconnection lines 24 are provided within the core region 50, and have ends that are aligned on an imaginary straight line B-B in an end of the core region 50. The first interconnection lines 24 can be further shortened, and charges that gather in the first interconnection lines 24 can be reduced.

As described above, the flash memory of the first embodiment has the first interconnection lines 24 that are not connected directly to the transistors in the peripheral circuit regions 52, but are connected to the transistors via the second interconnection lines 30. It is thus possible to reduce the lengths of the first interconnection lines 24 beyond the core region 50 and restrain the damage of the ONO film 12 resulting from the charge up caused when the interconnection lines are formed. The semiconductor device thus structured is very reliable.

### Second Embodiment

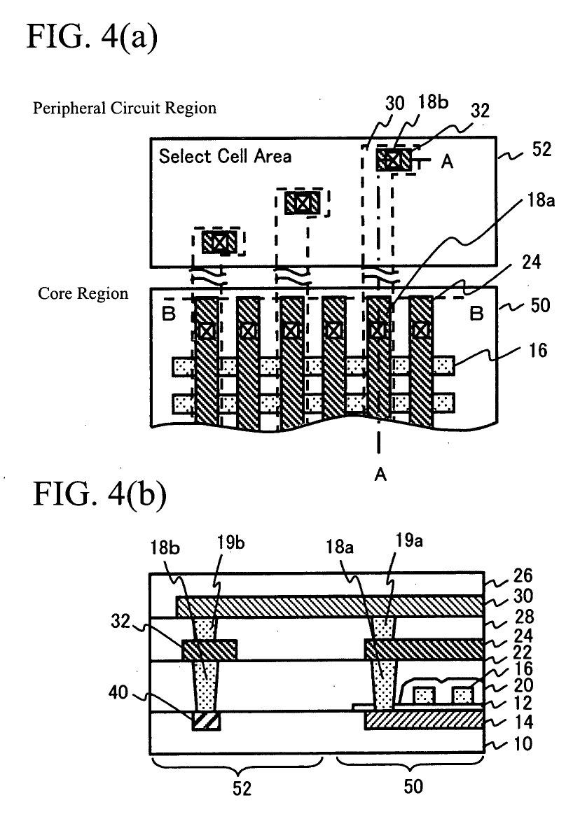

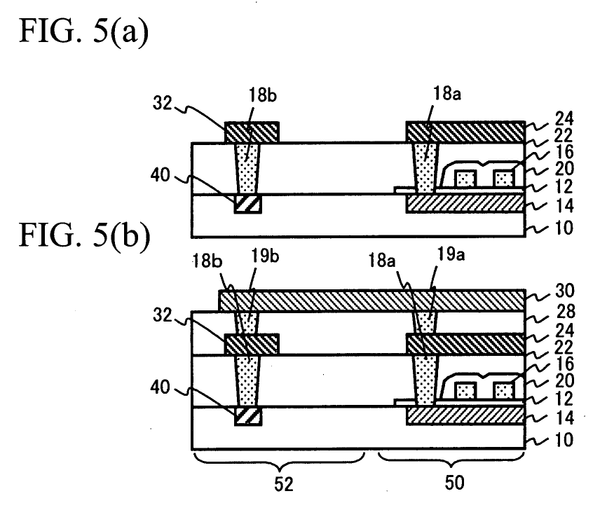

A second embodiment employs third interconnection lines 32 provided between the second interconnection lines 30 and the diffused regions 40. FIG. 4(a) is a top view of the second embodiment (in which the passivation film 26, and the interlayer insulating films 22 and 28 are not illustrated, and the second interconnection lines 30 are illustrated by broken lines). FIG. 4(b) show is a cross-sectional view taken along a line A-A shown in FIG. 4(a). FIGS. 5(a) and 5(b) show a method of fabricating the second embodiment, and illustrates cross sections taken along the line A-A. First, the fabrication method is described.

Referring to FIG. 5(a), the processes that are carried out until the first interlayer insulating film 22 is formed are the same as those shown in FIGS. 3(a) and 3(b). Contact holes 18a and 18b are formed in the first interlayer insulating film 22 so as to be connected to the bit lines 14 and the diffused regions 40. The first interconnection lines 24 that are connected to only the bit lines 14 and the third interconnection lines 32 that are connected to the diffused regions 40 of the transistors in the peripheral circuit regions 52 are simultaneously formed in a manner similar to that of the first embodiment. That is, the step of forming the first interconnection lines 24 includes a step of forming the first interconnection lines 32. Thus, the number of steps can be reduced.

Referring to FIG. 5(b), the second interlayer insulating film 28 are formed as in the case of the first embodiment. The contact holes 19a and 19b connected to the first interconnection lines 24 and the third interconnection lines 32 are formed in the second interlayer insulating film 28. As the first embodiment, the second interconnection lines 30 are formed. Then, the passivation film 26 is formed and the flash memory of the second embodiment is completed.

Even in the second embodiment, it is possible to restrain charge loss from the ONO film 12 as in the case of the first embodiment. Further, the following advantages can be obtained. In the first embodiment, when the contact holes 19a and 19 are simultaneously formed, the contact holes 18a may be over etched de to the difference in thickness between the interlayer insulating films. Thus, the surface of the interconnection lines 24 may be damaged and the contact resistances between the contact holes 19a and the first interconnection lines 24 may be increased. In contrast, the second embodiment does not have over etching when the contact holes 19 are formed. It is thus possible to reduce the contact resistances between the contact holes 19a and the first interconnection lines 24. It is further possible to reduce the charges that gather in the first interconnection lines 24.

The first and second embodiments employ the second interconnection lines 30 provided just above the first interconnection lines 24. Another interconnection lines may bring about similar effects when these interconnection liens are provided at a higher level than the first interconnection lines 30.

### Third Embodiment

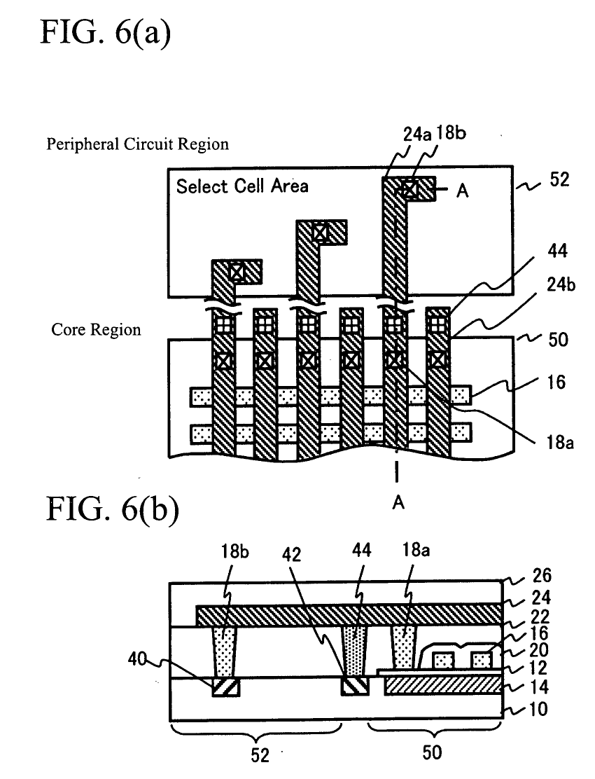

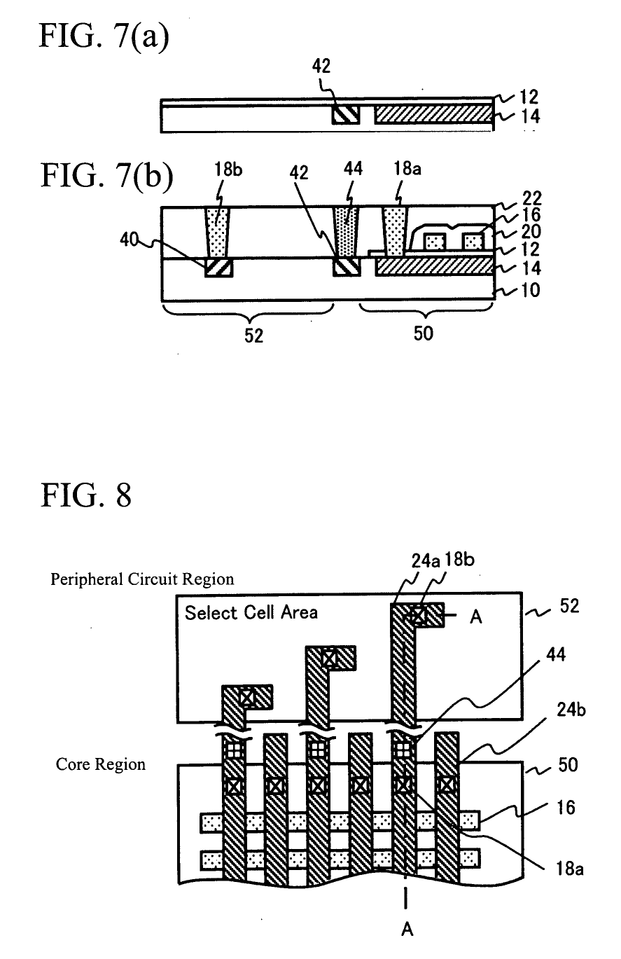

A third embodiment employs dummy contact holes 44 provided between the transistors in the peripheral circuit region 52 provided at each side of the core region 50 and the bit lines 14. FIG. 6(a) is a plan view (in which the passivation film 26 and the interlayer insulating film 22 are not shown), and FIG. 6(b) is a cross-sectional view taken along a line A-A shown in FIG. 6(a). FIGS. 7(a) and (b) show a method of fabricating the third embodiment, and illustrate the cross sections taken along the line A-A shown in FIG. 6(a). First, the fabrication method of the third embodiment is described.

Referring to FIG. 7(a), the ONO film 12 is formed on the p-type silicon semiconductor substrate 10 as in the case of the first embodiment. Arsenic is implanted in a given region in the semiconductor substrate in the core region 50 so as to form the bit lines 14, which function as the source and drain regions buried in the semiconductor substrate 10. Simultaneously, the dummy diffused regions 42 buried in the semiconductor substrate 10 are formed. The dummy contact holes 44 will be connected to the dummy diffused regions 42 later.

Referring to FIG. 7(b), the interlayer insulating film 22 are formed on the word lines 16, the silicon oxide film 20 and the bit lines 14 as in the case of the first embodiment. The contact holes 18a connected to the bit lines 14 are formed in the interlayer insulating film 22. Simultaneously, the dummy contact holes 44 connected to the dummy diffused regions 42 (that is, the semiconductor substrate 20) are formed. The dummy contact holes 44 are connected to the semiconductor substrate 10 and will be connected to the first interconnection lines 24 between the diffused regions 40 of the transistors and the bit lines 14 later. Further, the contact holes 18b connected to the diffused regions 40 of the transistors are simultaneously formed. The simultaneous forming of the contact holes 18a and 18b and the dummy contact holes 44 reduces the number of production steps.

After that, the first interconnection lines 24 are formed on the interlayer insulating film 22, the lines 24 being connected via the contact holes 18b to the diffused regions 40 of the transistors in the peripheral circuit regions 52 and being connected via the contact holes 18a to the bit lines 14. The first interconnection lines 24 are connected to the dummy diffused regions 42 via the dummy contact holes 44 in the section between the diffused regions 40 of the transistors and the bit lines 14. This arrangement causes charges on the charged-up wafer surface at the time of etching the metal layer (for example, aluminum) to thus form the first interconnection lines 24 to flow to the semiconductor substrate 10 via the dummy contact holes 44 and the dummy diffused regions 42. It is thus possible to reduce the charges that flow through the bit lines 14 via the contact holes 18a and to restrain the ONO film 12 from being damaged in the vicinity of the contact holes 18a.

The passivation film 26 is then formed, and the flash memory of the third embodiment is completed.

Referring to FIGS. 6(a) and 6(b), the flash memory of the third embodiment has bit lines 14 burned in the semiconductor substrate 10, the interlayer insulating film 22 formed on the bit lines 14, and the first interconnection lines 24 connected to the bit lines 14 via the contact holes 18a formed in the interlayer insulating film 22. The interlayer insulating film 22 has the dummy contact holes 44 connected to the first interconnection lines 24 and the semiconductor substrate 10. The dummy contact holes 44 are connected to the first interconnection lines 24 between the diffused regions and the bit lines 14. Further, the ONO film 12 is provided between the bit lines 14 and the interlayer insulating film 22, and has contact holes 18a.

In the third embodiment, the dummy contact holes 44 are provided in the regions between the core region 50 and the peripheral circuit regions 52. As this arrangement, the dummy contact holes 44 are preferably arranged in the vicinity of the contact holes 18a for the purpose of restraining the charges from flowing to the contact holes 18a at the time of forming the first interconnection lines 24. It is thus possible to more effectively restrain the charges from flowing to the contact holes 18a. The forming of the dummy contact holes 44 in the core region 50 may further facilitate to restrain the charges from flowing to the contact holes 18a at the time of forming the first interconnection lines 24.

The dummy contact holes 44 are connected to the dummy diffused regions 42 buried in the semiconductor substrate 10. Although the dummy contact regions 42 are not essential, it is preferable to use the dummy contact regions 42 in order to cause the charges on the charged-up wafer surface to more effectively flow the semiconductor substrate 10.

As described above, the flash memory of the third embodiment employs the dummy contact holes 44 connected to the first interconnection lines 24. It is thus possible to cause the charges on the charged-up surface to flow to the semiconductor substrate 10 via the dummy contact holes 44 and to restrain the damage of the ONO film 12. This restrains the charge loss from the ONO film 12 and improves the reliability of the flash memory.

FIG. 8 is a plan view of a variation of the third embodiment. This variation employs the dummy contact holes 44 and the dummy diffused regions 42 for only the first interconnection lines 24a connected to the transistors in the peripheral circuit regions 52. The variation brings about the same advantages as the third embodiment. The variation reduces the number of dummy contact holes 44, which further miniaturizes the memory cell.

The present invention is not limited to the specifically described embodiments, but various variations and modifications may be made within the scope of the present invention. For instance, the first through third embodiments employ the metal layer of aluminum formed by etching for making the interconnection lines. Even when another metal is used, charge up of the wafer surface is inevitable in dry etching. The present invention can be applied to the interconnection lines made of another metal, different etching machines and conditions used to form the interconnection lines.

What is claimed is:

1. A semiconductor device comprising:
a bit line formed in a semiconductor substrate;
a first interconnection line provided above the bit line and connected to the bit line; and
a second interconnection line provided above the first interconnection line and connected to the first interconnection line and a transistor in a peripheral region,
wherein the first interconnection line is connected to the transistor through the second interconnection line only.

2. The semiconductor device as claimed in claim 1 wherein the first interconnection line is formed in the core region or a region between the core region and the peripheral region only.

3. The semiconductor device as claimed in claim 1, further comprising a third interconnection line connected to the second interconnection line and the transistor,
wherein the second interconnection line is connected to the transistor through the third interconnection line only.

4. The semiconductor device as claimed in claim 1, further comprising an ONO film provided on the bit line and having a contact hole through which the bit line and the transistor are connected.

5. A semiconductor device comprising:
a bit line formed in a semiconductor substrate;
an interlayer insulating film provided above the bit line; and
a first interconnection layer provided on the interlayer insulating film and connected to the bit line through a contact hole formed in the interlayer insulating film,
wherein the interlayer insulating film has a dummy contact hole connected to the first interconnection line and the semiconductor substrate, the dummy contact hole being connected to a portion of the first interconnection line between a transistor in a peripheral region and the bit line.

6. The semiconductor device as claimed in claim 5, wherein the dummy contact hole is formed in a core region or a region between the core region and the peripheral region.

7. The semiconductor device as claimed in claim 6, wherein the dummy contact hole is connected to a dummy diffused region formed in the semiconductor substrate.

8. The semiconductor device as claimed in claim 1, further comprising;
an ONO film provided between the bit line and the interlayer insulating film,
wherein the contact hole is formed in the ONO film.

9. The semiconductor device as claimed in claim 1, wherein the peripheral region is a select cell area.

10. A method of fabricating a semiconductor device comprising:
forming a bit line in a semiconductor substrate;
forming a first interconnection line, above the bit line, connected to the bit line; and
forming a second interconnection line, above the first interconnection line, connected to the first interconnection line and a transistor in a peripheral region,
wherein the first interconnection line is connected to the transistor through the second interconnection line only.

11. The method as claimed in claim 10, wherein the step of forming the first interconnection line further comprises a step of forming a third interconnection line connected to the transistor and to be connected the second interconnection line.

12. The method as claimed in claim 10, further comprising forming an ONO film on the semiconductor substrate,
the first interconnection line being connected to the bit line through the contact hole formed in the ONO film.

13. A method of fabricating a semiconductor device comprising:
forming a bit line on a semiconductor substrate;
forming an interlayer insulating film above the bit line;
forming a contact hole, in the interlayer insulating film, connected to the bit line; and
forming a first interconnection line, on the interlayer insulating film, connected to a transistor in a peripheral region and the bit line,
wherein the step of forming the contact hole includes a step of forming a dummy contact hole connected to the semiconductor substrate and for connection to the first interconnection line between the transistor and the bit line.

14. The method as claimed in claim 13, wherein the step of forming the bit line includes a step of forming a dummy diffused region in the semiconductor substrate for connection to the dummy contact hole.

15. The method as claimed in claim 13, further comprising forming an ONO film on the semiconductor substrate,
wherein the step of forming the contact hole includes a step of forming the contact hole in the ONO film.

16. The method as claimed in claim 10, wherein the peripheral region is a core select cell area.
